(19) United States
(12) Patent Application Publication
(10) Pub. No.: US 2004/0038495 A1
(43) Pub. Date: Feb. 26, 2004

(54) Method of providing a thick thermal oxide in trench isolation

(76) Inventors: Karsten Wieczorek, Dresden (DE); Stephan Kruegel, Boxdorf (DE); Ralf van Bentum, Radebeul (DE)

Correspondence Address: J. Mike Amerson, Williams, Morgan & Amerson, P.C., Suite 1100, 10333 Richmond, Houston, TX, 77042, US

(21) Appl. No.: 10/359,994

(22) Filed: Feb. 6, 2003

(30) Foreign Application Priority Data
Jul. 30, 2002 (DE) 102 34 699.2

(51) Int. Cl. H01L 21/76

(52) U.S. Cl. 438/431; 438/435

(57) ABSTRACT

A method of providing a thick thermal oxide in trench isolation is disclosed, wherein an additional polysilicon layer, blanket deposited in a chemical vapor deposition process, is employed. The polysilicon layer is subsequently, in a thermal oxidation process, transformed into a thick thermal liner oxide. Advantageously, forming the thick liner oxide by oxidation of the additional polysilicon layer reduces the formation of a “bird's beak” and, thus, reduces the introduction of mechanical stress into the semiconductor device. Due to the employment of a thick thermal liner oxide, the formation of divots is also minimized. Thus, the device stability and reliability is improved.

### BACKGROUND OF THE INVENTION

1. Field of the Present Invention

The present invention relates to the field of the fabrication of semiconductor devices, and, more particularly, to the formation of trench isolation structures that electrically isolate adjacent regions.

2. Description of the Related Art

The trend in semiconductor device fabrication towards increasing density of circuit components has driven the shift from local isolation layers between transistors to trench isolation. Accordingly, trench isolation has become the standard technique in the sub 250 nm semiconductor device generations. Trench isolation techniques minimize the amount of substrate surface area consumed due to, with respect to the plane of the substrate surface, vertically oriented structures. The lateral dimension of the vertical structures or trenches may be shrunk to 200 nm or even less in future device generations.

With the introduction of vertical structures, however, new drawbacks concerning the semiconductor device isolation are emerging. The trenches are typically formed by a plasma etch process. The plasma etch generates lattice dislocations in the crystal structure and sharp upper corners at the sidewalls or edges of the adjacent active regions of the semiconductor device. Lattice dislocation and, particularly, sharp corners are known to increase current leakage in field effect transistors, especially in narrow width channel devices. The corner effects are more dominant in narrow width channel devices, since the channel regions of these devices are scaled down in the width direction, i.e., in the direction perpendicular to the channel length direction, whereas the edge effects are unchanged. To reduce the edge effects, thermal oxidation is routinely used to form a thermal liner oxide, to provide concurrently the upper trench isolation corner with a round shape, and to repair the lattice dislocations at the sidewalls of the adjacent active regions to suppress the related current leakage.

A further problem in the trench isolation process is the formation of divots, i.e., field oxide recesses adjacent to the active region of the semiconductor device. Divots may also cause current leakage and may further reduce the device stability and the integrity of the gate insulation layer. To prevent or reduce the formation of divots, the thickness of the thermal liner oxide, generated in the thermal oxidation process, may be increased. Increasing the liner oxide thickness, however, introduces additional undesirable mechanical stress into the semiconductor device, particularly in semiconductor-on-insulator (SOI) devices. The introduced stress, however, may result in device performance degradation.

To explain the trench isolation process, according to a typical prior art process sequence, in detail, the process flow for forming a shallow trench isolation in an SOI field effect transistor is described with reference to FIGS. 1a-1h, which illustrate schematic cross-sectional views in the width direction, which is the direction perpendicular to the channel length direction, of the partially formed field effect transistors.

FIG. 1a schematically depicts an SOI structure 1 that comprises a substrate 10 with a buried oxide (BOx) layer 20, a silicon (Si) layer 30 formed thereon, a pad oxide layer 40 and a silicon nitride (Si₃N₄) layer 50 formed on the silicon layer 30. A typical process flow for forming the SOI structure 1 includes well-known oxidation and deposition techniques and thus a description thereof will be omitted.

FIG. 1b schematically depicts the SOI structure 1 with a silicon nitride region 51, a pad oxide region 41, an active silicon region 31 forming active regions, in which a transistor element may be formed, and a trench 61 separating the adjacent active silicon regions 31. Forming the trench 61 may include an isolation lithography process (resist not shown) and a subsequent anisotropic trench etch process in which the pad oxide layer 40 is employed as an etch stop layer during patterning of the silicon nitride layer 50. A further anisotropic plasma etch process is employed to etch the silicon layer 30, wherein process parameters are controlled to obtain a desired slope of the sidewalls in the range from 70-85 degrees.

FIG. 1c schematically depicts the SOI structure 1 after completion of a thermal oxidation employed to form a liner oxide 43 at the sidewall 32 of the trench 61. A thin liner oxide 43 (left figure) and a thick liner oxide 43 (right figure), respectively, are depicted and form together with the pad oxide region 41 the thermal oxide 42.

The thickness of the thermal liner oxide 43 is determined by the duration, temperature and oxygen concentration of the ambient of the oxidation process. The thickness of the liner oxide 43 strongly affects the electrical and mechanical characteristics of the semiconductor device to be formed. A thin thermal liner oxide 43 tends to promote the formation of divots 85 in the subsequent chemical mechanical polishing process and the subsequent etch processes due to the stress in the silicon/silicon dioxide interface at the sidewalls 32 of the trench 61.

Thick thermal liner oxides 43 (right side), on the other hand, introduce additional mechanical stress into the semiconductor structure caused by a first “bird's beak” 41a formed in the pad oxide region 41 and a second “bird's beak” 42a formed in the silicon 31/buried oxide layer 20 interface, due to oxygen diffusion during the thermal oxidation process. The second “bird's beak” 42a leads to a bending effect in the active silicon region 31.

FIG. 1d schematically depicts the SOI structure 1 with a deposited silicon oxide layer 80 formed thereon by well-known deposition techniques, such as a chemical vapor deposition process. The deposited silicon oxide layer 80 tends to show a higher etch rate adjacent to the thermal liner oxide interface resulting in an increased formation of divots 85 (see FIG. 1g) in the subsequent CMP and etch processes.

FIG. 1e schematically depicts the SOI structure 1 after a CMP process to remove excess material of the silicon oxide layer 80 and to planarize the surface of the SOI structure 1. During the CMP process, the silicon nitride region 51 acts as a stop layer and is partially removed to form a reduced silicon nitride region 52. The trenches 61 are filled with the remaining silicon oxide indicated by 81 up to a level that is slightly lower than the surface of the reduced silicon nitride region 52, owing to different removal rates of the silicon oxide 81 and the silicon nitride region 52. After the CMP process, the silicon oxide 81 that fills the trenches 61 is densified in an annealing process.

FIG. 1f schematically depicts the SOI structure 1 after stripping the remaining silicon nitride region 52. The silicon nitride region 52 is stripped by etching selectively with respect to the silicon dioxide 81, thereby generating divots 85, separating the thermal liner oxide 43 and the thermal pad oxide region 41 of the thermal oxide layer 42, as shown in the left figure. The thick thermal liner oxide 43 (right side) is substantially not affected by divot formation. It is assumed that the divots 85 are caused by an etch selectivity reduction between the silicon nitride region 52 and the silicon oxide 81 due to etch rate raise in the liner oxide 43 caused by mechanical stress in the silicon/silicon oxide interface.

FIG. 1g schematically depicts the SOI structure 1 after stripping the pad oxide region 41. During etching the pad oxide region 41, the divots 85 shown in the left figure are further increased. In the thick liner oxide 43 (right side), substantially no divots are generated in the stripping processes.

FIG. 1h schematically depicts the SOI structure 1 after growing a gate insulation layer 46 and depositing a gate polysilicon layer 90.

In the embodiment shown in the left figure, the surface of the SOI structure 1, prior to the deposition of the gate polysilicon, shows the divots 85 generated at the sidewalls 32 of the active silicon region 31. After blanket deposition of the gate polysilicon layer 90, the divots 85 are filled with polysilicon, so that the gate polysilicon layer 90 is partially “wrapped” around the active silicon region 31. This so-called “polygate wraparound” results in increased junction leakage and reduced integrity of the gate insulation layer. Particularly, the reduction of the threshold voltage associated therewith and the appearance of an increase of the drain-source current in the sub-threshold region in narrow channel devices are severe drawbacks in the conventional trench isolation process.

Although in the SOI structure 1 illustrated in the right figure substantially no divots 85 are formed, the “bird's beaks” 41a, 42a lead to device degradation. In semiconductor-on-insulator (SOI) devices, “bird's beaks” 41a, 42a generation has been proven to increase unwanted mechanical stress that may result in device performance degradation or even in a device failure. Moreover, additional stress, introduced in the SOI devices, causes silicon bending and may even lead to a dislocation of the silicon active region 31.

In view of the aforementioned drawbacks of the conventionally formed isolation trenches, it is desirable to provide a method of forming a trench isolation with reduced stress and/or divot generation.

### SUMMARY OF THE INVENTION

According to the present invention, a method is provided wherein the thermal liner oxide in a trench isolation process is formed by depositing an additional polysilicon layer that is subsequently at least partially transformed into a thermal liner oxide during an oxidation process.

According to one illustrative embodiment of the present invention, a method of forming a trench isolation in a semiconductor device comprises providing a semiconductor substrate and forming a trench in the semiconductor substrate to define an active region. Moreover, the method comprises depositing a semiconductor layer at least in the trench and transforming the semiconductor layer in the trench at least partially into an oxide. Additionally, the method comprises filling the trench with an insulating material.

According to another illustrative embodiment of the present invention, a method of forming a trench isolation in a semiconductor device comprises providing a substrate having formed on a surface an insulating layer and a silicon layer formed over the insulating layer. The method further comprises forming a trench in the silicon layer, the trench having sidewalls, and depositing a polysilicon layer to cover at least the sidewalls of the trench. Moreover, the method comprises transforming the polysilicon layer, at least partially, into silicon dioxide and filling the trench with an insulating material.

### BRIEF DESCRIPTION OF THE DRAWINGS

The invention may be understood by reference to the following description taken in conjunction with the accompanying drawings, in which like reference numerals identify like elements, and in which:

FIGS. 1a-1h schematically depict a cross-sectional view, in the width direction of partially shown field effect transistors, of an SOI structure, illustrating a typical process flow of a shallow trench isolation process according to the prior art; and

FIGS. 2a-2g schematically depict cross-sectional views, in the width direction of the partially shown field effect transistors, of an SOI structure, illustrating a shallow trench isolation process in accordance with one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various structures of the semiconductor device and the implant regions are depicted in the drawings as having very precise, sharp configurations and profiles, those skilled in the art recognize that, in reality, these regions and structures may not be as precise as indicated in the drawings. Additionally, the relative sizes of the various features and implant regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

According to the present invention, a method of forming a trench isolation structure for semiconductor devices with an improved characteristic is provided. The method may reduce or even completely overcome the drawbacks related to the trade-off between stress reduction and polygate wraparound related effects. The method allows the formation of a thick thermal oxide layer without introducing additional stress to the semiconductor device by additionally depositing a polysilicon layer on the substrate surface prior to thermal oxidation. The polysilicon layer is typically blanket deposited by a chemical vapor deposition process, for example, in a low pressure chemical vapor deposition process. Prior to the deposition process, a cleaning process may be performed to remove remaining contamination from the prior etch process. A first oxidation process to repair lattice damage caused by the plasma etching and to achieve the necessary corner rounding may be performed prior to the deposition of the polysilicon layer. In a separate oxidation process, the polysilicon layer is at least partially transformed into silicon oxide. With regard to the thermal budget, however, the oxidation of the polysilicon layer and of the active silicon region, to achieve the necessary corner rounding, is preferably performed in a single oxidation process leading to a completely transformed polysilicon layer and to an oxidized edge of the active silicon region to achieve the desired electrical and mechanical characteristics of the semiconductor device.

Thus, the method allows the formation of a thick thermal liner oxide without consuming unduly amounts of silicon from the edge of the active region. Due to the reduced loss of silicon in the lateral dimension of the active region, higher maximum transistor drive currents may be achieved. Forming the thick thermal liner oxide by oxidation of an additional deposited polysilicon layer also reduces the stress introduced to the semiconductor device that may be formed in and on the active region, since less oxygen is diffused to the interface between the silicon nitride layer and the active silicon layer leading to accordingly reduced mechanical stress. On the other hand, the thick thermal liner oxide prevents excessive field oxide loss adjacent to the upper trench isolation corner during the subsequent isotropic etch and cleaning processes. Thus, gate wraparound will effectively be reduced and accordingly the device stability and the integrity of the gate insulation layer improved.

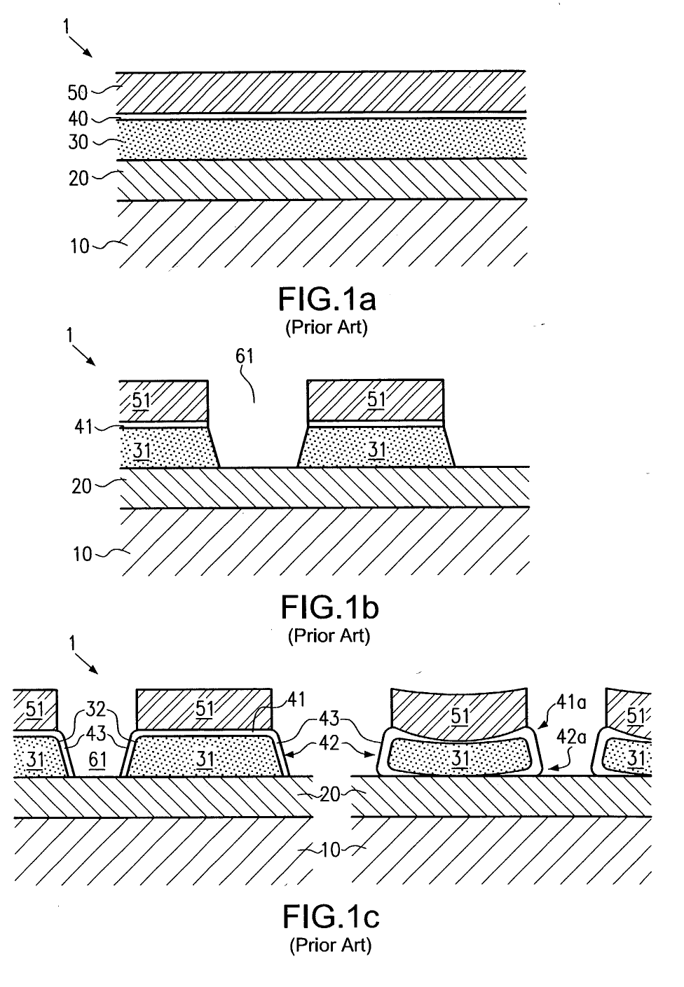

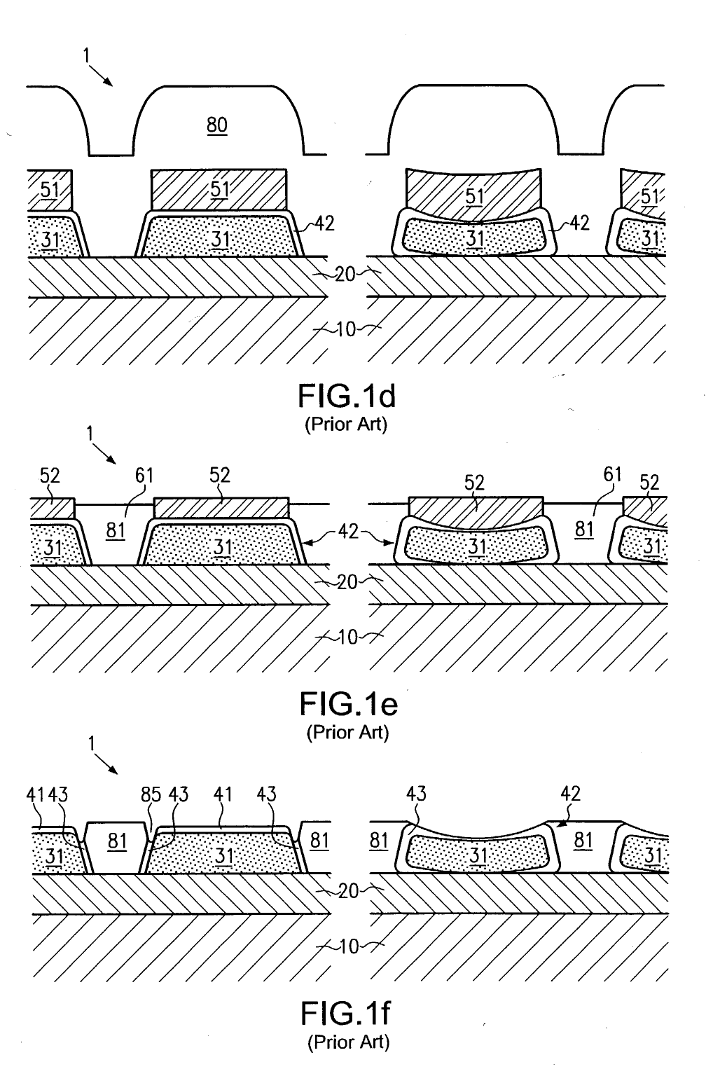

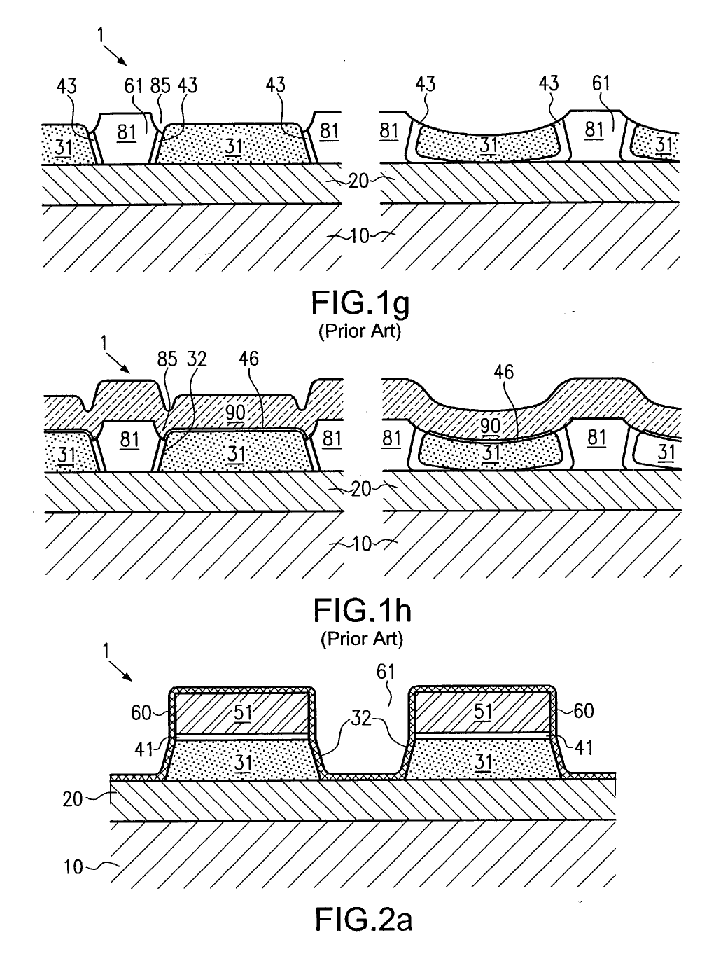

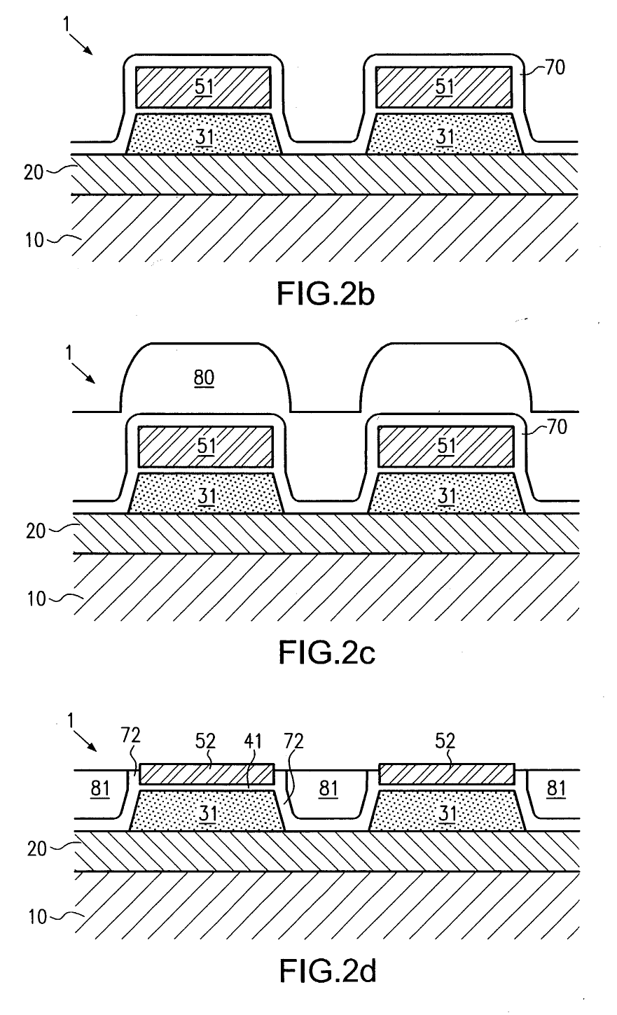

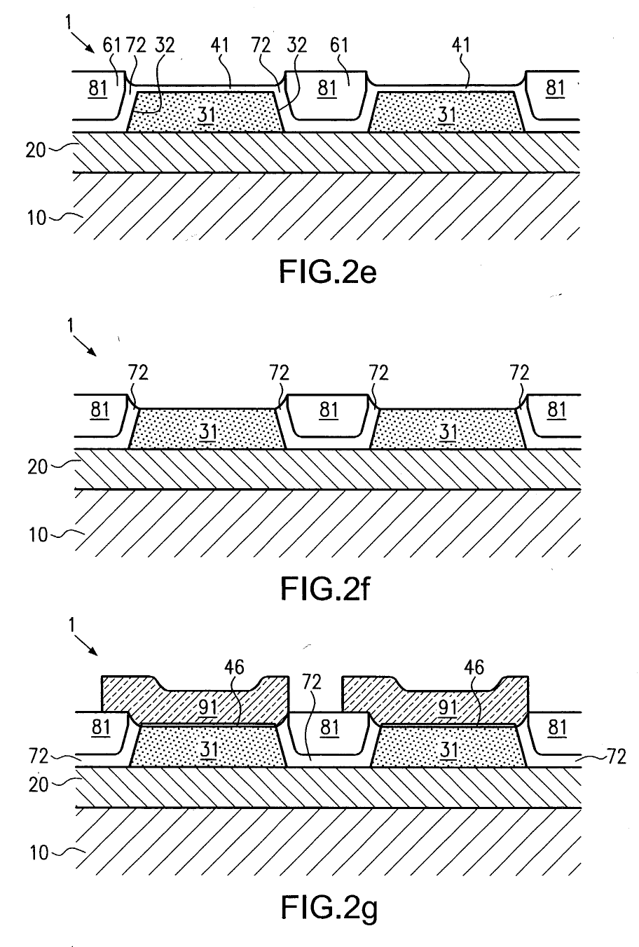

With reference to FIGS. 2a-2g, illustrative embodiments according to the present invention will now be described. In FIGS. 2a-2g, the same reference signs as in FIGS. 1a-1h are used to denote similar or equal components and parts. FIGS. 2a-2g depict, like the FIGS. 1a-1h, schematic cross-sectional views in the width direction, which is perpendicular to the channel length direction, of a partially formed SOI field effect transistor.

The embodiments illustrated in FIGS. 2a-2g refer to a the trench isolation process that is performed on an SOI substrate with a deposited semiconductor layer. The semiconductor layer may comprise any appropriate semiconductor material, for example, polysilicon or germanium. In the embodiment described with respect to FIGS. 2a-2g, a polysilicon layer 60 is utilized. Moreover, the substrate employed is not limited to an SOI substrate, and any other substrate, for example, a silicon or a germanium substrate, may be used.

The illustrative embodiments according to the present invention employ initially the same steps as described with respect to the FIGS. 1a and 1b. The isolation lithography and the silicon trench etch are performed in the same way and on the same substrate structure. Thus, FIGS. 2a-2g schematically depict only that part of the process flow of the shallow trench isolation process that is different from the process flow illustrated in FIGS. 1c-1h.

FIG. 2a schematically depicts the SOI structure 1 after trench etching and deposition of the polysilicon layer 60. The SOI structure 1 includes the substrate 10 with the buried oxide layer 20 thereon, and the patterned layers formed over the buried oxide layer 20 comprising the active silicon region 31, the pad oxide region 41 and the silicon nitride region 51. The trench 61 is defined by the sidewalls 32 of two adjacent active silicon regions 31 and the top surface of the buried oxide layer 20. The blanket deposited polysilicon layer 60 is formed on the silicon nitride region 51 and within the trench 61.

The polysilicon layer 60 is deposited by a chemical vapor deposition (CVD) process, or example, a low pressure chemical vapor deposition (LPCVD) process or any other appropriate deposition process able to deposit the polysilicon in the trench 61, especially at the sidewalls 32, with the required thickness and quality. Prior to the deposition process, a cleaning process may be performed to remove the residue from the plasma etch process curried out to form the trench 61. In one illustrative embodiment, the polysilicon layer 60 may have a thickness that ranges from approximately 10-80 nm.

FIG. 2b schematically depicts the SOI structure 1 with the polysilicon layer 60 at least partially transformed into a silicon oxide layer 70. Although the drawings depict that the entirety of the polysilicon layer 60 is transformed into a silicon oxide layer 70, the present invention may be employed in situations where only a portion of the layer of polysilicon 60 is transformed into silicon dioxide. Thus, unless specifically recited in the attached claims, the present invention should not be considered as limited to the transformation of the entire thickness of the layer of polysilicon into silicon dioxide.

The polysilicon layer 60 is transformed into the silicon oxide layer by exposing the polysilicon layer 60 to an oxidizing ambient at low temperatures in the range of approximately 800-1050° C., and preferably in the temperature range of approximately 850-950° C. The transforming and the necessary corner rounding may be achieved in a single process or in two separate processes.

FIG. 2c schematically depicts the SOI structure 1 with an additionally deposited silicon oxide layer 80. The silicon oxide layer 80 is deposited in a chemical vapor deposition process, for example, in a high density plasma chemical vapor deposition process (HDPCVD) or in a sub-atmospheric chemical vapor deposition process (SACVD). Any other appropriate deposition process may be used that is able to deposit the silicon dioxide layer 80 with the desired thickness and with the desired uniformity of the material characteristics, particularly with the desired etch rate uniformity. In another embodiment, the material may comprise other dielectric materials, such as silicon nitride, silicon oxynitride and the like.

FIG. 2d schematically depicts the SOI structure 1 after performing the chemical mechanical polishing (CMP) process as described with respect to FIG. 1f. FIG. 2e schematically depicts the SOI structure 1 after the silicon nitride region 52 strip process. The employment of a thick thermal liner oxide 70, 72, generated from the polysilicon layer 60 at the sidewalls 32 of the trench 61, prevents or at least reduces the formation of divots 85 adjacent to the active silicon region 31. It is assumed that the reduced stress in the silicon 31/silicon dioxide 70, 72 interface reduces the etch rate in this interface, and, thus, the formation of divots 85 may at least be reduced or may even be completely prevented as shown in FIG. 2e.

FIG. 2f schematically depicts the SOI structure 1 after stripping the pad oxide region 41 as described with respect to FIG. 1h. The formation of divots 85 is at least reduced or even prevented also during the pad oxide region 41 strip process. Concurrently, bending of the active silicon region 31 is at least reduced or even prevented. Thus, the SOI structure 1 in the illustrative embodiment shows the advantages of a thin and a thick liner oxide described with respect to FIG. 1c without showing the respective disadvantages, particularly divot formation and silicon bending.

FIG. 2g schematically depicts the SOI structure 1 with a deposited and patterned polysilicon gate layer 91. Due to the substantially avoided formation of divots and silicon bending, gate wraparound may substantially be prevented and, thus, the devices fabricated in accordance with this embodiment are showing an improved device stability and reliability.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method of forming a trench isolation in a semiconductor device, the method comprising:
providing a semiconductor substrate;
forming a trench in the semiconductor substrate to define an active region;
depositing a semiconductor layer at least in the trench;
transforming the semiconductor layer in said trench at least partially into an oxide; and
filling the trench with an insulating material.

2. The method of claim 1, further comprising rounding a corner of said trench by oxidizing the semiconductor substrate.

3. The method of claim 1, wherein transforming the semiconductor layer comprises oxidizing the semiconductor substrate to achieve rounding of a corner of said trench.

4. The method of claim 1, wherein the semiconductor substrate comprises at least one insulating layer formed over a surface of the semiconductor substrate.

5. The method of claim 4, wherein the semiconductor substrate comprises silicon.

6. The method of claim 5, wherein the at least one insulating layer comprises at least one of a silicon oxide layer and a silicon nitride layer.

7. The method of claim 5, wherein the at least one insulating layer comprises a silicon oxide layer and a silicon nitride layer.

8. The method of claim 1, wherein the trench is filled with an insulating material.

9. The method of claim 8, wherein the insulating material comprises silicon oxide.

10. The method of claim 8, wherein the insulating material is deposited by a chemical vapor deposition process.

11. The method of claim 10, wherein the chemical vapor deposition process is at least one of a high density plasma chemical vapor deposition process and a sub atmospheric chemical vapor deposition process.

12. The method of claim 1, wherein a cleaning process is performed prior to the depositing of the semiconductor layer.

13. The method of claim 1, wherein the semiconductor layer is deposited in a chemical vapor deposition process.

14. The method of claim 13, wherein the chemical vapor deposition process is a low pressure chemical vapor deposition process.

15. A method of forming a trench isolation in a semiconductor device, the method comprising:
providing a substrate having formed on a surface an insulating layer and a silicon layer formed over the insulating layer;
forming a trench in the silicon layer, said trench having sidewalls;
depositing a polysilicon layer to cover at least the sidewalls of the trench;
transforming the polysilicon layer at least partially into silicon dioxide; and
filling the trench with an insulating material.

16. The method of claim 15, further comprising rounding a corner of said trench by oxidizing the silicon layer.

17. The method of claim 15, wherein transforming the polysilicon layer comprises oxidizing the silicon layer to achieve rounding of a corner of said trench.

18. The method of claim 15, wherein the substrate comprises at least one insulating layer over the silicon layer.

19. The method of claim 18, wherein the at least one insulating layer comprises at least one of a silicon oxide layer and a silicon nitride layer.

20. The method of claim 18, wherein the at least one insulating layer comprises a silicon oxide layer and a silicon nitride layer.

21. The method of claim 15, wherein the trench is filled with an insulating material.

22. The method of claim 21, wherein the insulating material comprises silicon oxide.

23. The method of claim 21, wherein the insulating material is deposited by a chemical vapor deposition process.

24. The method of claim 23, wherein the chemical vapor deposition process is at least one of a high density plasma chemical vapor deposition process and a sub atmospheric chemical vapor deposition process.

25. The method of claim 15, wherein a cleaning process is performed prior to the depositing of the polysilicon layer.

26. The method of claim 15, wherein the polysilicon layer is deposited in a chemical vapor deposition process.

27. The method of claim 26, wherein the chemical vapor deposition process is a low pressure chemical vapor deposition process.
